(19) United States
(12) Patent Application Publication
(10) Pub. No.: US 2006/0038229 A1
(43) Pub. Date: Feb. 23, 2006

(54) Semiconductor device

(75) Inventors: Yoshinori Tsuchiya, Yokohama-shi (JP); Junji Koga, Yokosuka-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/116,327

(22) Filed: Apr. 28, 2005

(30) Foreign Application Priority Data
Aug. 20, 2004 (JP) 2004-240846

(51) Int. Cl. H01L 21/00; H01L 27/01; H01L 21/84; H01L 27/12; H01L 31/0392

(52) U.S. Cl. 257/351

(57) ABSTRACT

Disclosed is a semiconductor device comprising a semiconductor substrate having isolation regions, and a MIS transistor comprising a gate electrode formed above the semiconductor substrate with a gate insulating film interposed therebetween, and a pair of contact layers formed on the semiconductor substrate sandwiching the gate electrode, the contact layers having an interfacial layer at an interface between the semiconductor substrate and the contact layers, the interfacial layer comprising a metal silicide containing at least one selected from a group consisting of Er, Gd, Tb, Dy, Ho, Tm, Yb, Lu, and Pt.

### CROSS-REFERENCE TO RELATED APPLICATIONS

This application is based upon and claims the benefit of priority from prior Japanese Patent Application No. 2004-240846, filed Aug. 20, 2004, the entire contents of which are incorporated herein by reference.

### BACKGROUND OF THE INVENTION

1. Field of the Invention

The present invention relates to a semiconductor device, and in particular, to a CMOS device constituting a silicon large scale integrated circuit that realizes advanced information processing.

2. Description of the Related Art

Silicon super-integrated circuits are one of the fundamental technologies that will support the advanced information society in the future. To improve the functions of an integrated circuit, it is necessary to improve the performance of a CMOS device, which is a component of the integrated circuit. The performance of element devices has been basically improved on the basis of the proportional reduction rule (Scaling rule). However, in recent years, various physical limits have made it difficult to improve the performance of element devices by sharply reducing their sizes and to operate the devices themselves.

With a drastic reduction in the depth of a diffusion region, the roughness of a silicide/Si interface results in electric field concentration. This increases junction leakage current. The junction leakage current must be reduced for a source/drain region. At the same time, the sheet resistance of the source/drain region must be reduced. To achieve this, a method has been proposed which makes Si amorphous before the formation of silicide to improve the interface roughness. A method has also been proposed which reduces resistivity by forming a composite film of transition metal silicide. With either method, roughness of the order of several nm to several tens of nm is still present on the silicide/Si interface.

For devices of the 32-nm technology generation, the international semiconductor road map still requires that silicide offer a low resistivity of 15 μΩ·cm or less. However, there has not been found any electrode silicide material or its structure which has a flat interface at an atomic level and exhibits low resistivity.

### BRIEF SUMMARY OF THE INVENTION

A semiconductor device according to one aspect of the present invention comprises a semiconductor substrate having isolation regions; and a MIS transistor comprising a gate electrode formed above the semiconductor substrate with a gate insulating film interposed therebetween, and a pair of contact layers formed on the semiconductor substrate sandwiching the gate electrode, the contact layers having an interfacial layer at an interface between the semiconductor substrate and the contact layers, the interfacial layer comprising a metal silicide containing at least one selected from a group consisting of Er, Gd, Tb, Dy, Ho, Tm, Yb, Lu, and Pt.

A semiconductor device according to another aspect of the present invention comprises a semiconductor substrate having isolation regions; and a MIS transistor comprising a gate electrode formed above the semiconductor substrate with a gate insulating film interposed therebetween, a pair of source/drain heavily impurity doped regions formed in the semiconductor substrate, and a pair of contact layers formed on the a pair of source/drain heavily impurity doped regions and having an interfacial layer at the interface, the interfacial layer comprising a metal silicide containing at least one selected from a group consisting of Er, Gd, Tb, Dy, Ho, Tm, Yb, Lu, and Pt.

A semiconductor device according to another aspect of the present invention comprises
a semiconductor substrate having isolation regions; an n-type MIS transistor having a diffusion region formed in the semiconductor substrate, a gate electrode formed above the semiconductor substrate with a gate insulating film interposed therebetween, and a silicide layer formed above the diffusion region with a first interfacial layer interposed therebetween, the first interfacial layer comprising a metal silicide containing at least one selected from a group consisting of Er, Gd, Tb, Dy, Ho, Tm, Yb, Lu, and Pt; and a p-type MIS transistor having a diffusion region formed in the semiconductor substrate, a gate electrode formed above the semiconductor substrate with a gate insulating film interposed therebetween, and a silicide layer formed above the diffusion region with a second interfacial layer interposed therebetween, the second interfacial layer comprising the metal silicide containing the same metal as the first interfacial layer in the n-type MIS transistor.

### BRIEF DESCRIPTION OF THE SEVERAL VIEWS OF THE DRAWING

FIG. 1 is a sectional view of a semiconductor device according to an embodiment of the present invention;

FIGS. 2A and 2B are electron micrographs of an interface of a silicide layer deposited on an Si(100) substrate;

FIG. 3 is a graph illustrating a reverse-direction leakage current characteristic of a Schottky diode;

FIG. 4 is a sectional view illustrating a step of a method for manufacturing a semiconductor device according to one embodiment of the present invention;

FIG. 5 is a sectional view illustrating a step following FIG. 4;

FIG. 6 is a sectional view illustrating a step following FIG. 5;

FIG. 7 is a sectional view of a semiconductor device according to another embodiment of the present invention;

FIG. 8 is a sectional view of a semiconductor device according to another embodiment of the present invention;

FIG. 9 is a sectional view illustrating a step of a method for manufacturing a semiconductor device according to another embodiment of the present invention;

FIG. 10 is a sectional view illustrating a step following FIG. 9;

FIG. 11 is a sectional view illustrating a step following FIG. 10;

FIG. 12 is a sectional view of a semiconductor device according to another embodiment of the present invention;

FIG. 13 is a sectional view of a semiconductor device according to another embodiment of the present invention;

FIG. 14 is a sectional view illustrating a step of a method for manufacturing a semiconductor device according to another embodiment of the present invention;

FIG. 15 is a sectional view illustrating a step following FIG. 14;

FIG. 16 is a sectional view illustrating a step following FIG. 15;

FIG. 17 is a sectional view of a semiconductor device according to another embodiment of the present invention;

FIG. 18 is a sectional view of a semiconductor device according to another embodiment of the present invention;

FIG. 19 is a sectional view of a semiconductor device according to another embodiment of the present invention;

FIG. 20 is a sectional view illustrating a step of a method for manufacturing a semiconductor device according to another embodiment of the present invention;

FIG. 21 is a sectional view illustrating a step following FIG. 20;

FIG. 22 is a sectional view illustrating a step following FIG. 21;

FIG. 23 is a sectional view illustrating a step following FIG. 22;

FIG. 24 is a sectional view of a semiconductor device according to another embodiment of the present invention;

FIG. 25 is a sectional view of a semiconductor device according to another embodiment of the present invention;

FIG. 26 is a sectional view of a semiconductor device according to another embodiment of the present invention;

FIG. 27 is a sectional view of a semiconductor device according to another embodiment of the present invention;

FIG. 28 is a sectional view illustrating a step of a method for manufacturing a semiconductor device according to another embodiment of the present invention;

FIG. 29 is a sectional view illustrating a step following FIG. 28; and

FIG. 30 is a sectional view illustrating a step following FIG. 29.

### DETAILED DESCRIPTION OF THE INVENTION

Embodiments of the present invention will be described with reference to the drawings.

### Embodiment 1

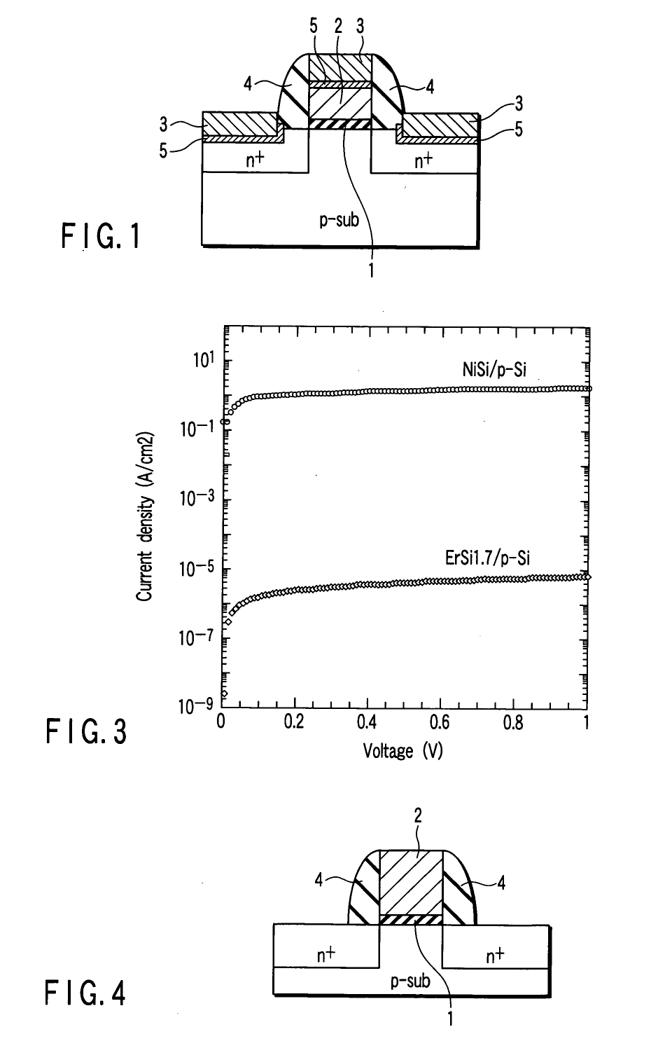

FIG. 1 is a sectional view of a semiconductor device according to this embodiment.

A gate electrode is formed on a p-type silicon substrate with a gate insulating film 1 formed of a thermal-grown-silicon oxide film interposed therebetween. The gate insulating film 1 desirably has a film thickness of 2 nm or less. The gate electrode has a structure in which a heavily phosphorous doped polycrystalline silicon layer 2, an ErSi_{1.7} layer 5, and an NiSi layer 3 are sequentially stacked. As shown in the figure, gate sidewalls 4 comprising silicon oxide films are provided on the sides of the gate insulating film and gate electrode to a film thickness of about 30 nm. A source region and a drain region are formed in the p-type silicon substrate sandwiching the gate insulating film 1; the source and drain regions are heavily n-type impurity doped regions.

A silicide layer is formed on these impurity regions. The silicide layer has an interfacial layer at the interface between itself and the heavily n-type impurity doped regions, the interfacial layer comprising the ErSi_{1.7} layer 5. The interface between the ErSi_{1.7} layer 5 and the heavily n-type impurity doped regions is flat at the atomic level. The NiSi layer 3 is provided on the interfacial layer. In this case, the ErSi_{1.7} layer 5 has a film thickness of about 2 nm, and the NiSi layer 3 has a film thickness of about 8 nm. Thus, an n-type MOS transistor is constructed on the p-type silicon substrate.

Arsenic may be doped, as impurities, into the polycrystalline silicon layer 2, constituting the gate electrode. The gate electrode may be wholly replaced with metal material, metal nitride, metal silicide, or metal germanosilicide. It is preferable to select such a material for the gate material as is suitable for a threshold voltage required for each technical generation of devices.

Further, the gate insulating film 1 may be composed of an insulating material having a larger dielectric constant than the silicon oxide film (high-dielectric insulating film). Such a material includes, for example, Si₃N₄, Al₂O₃, Ta₂O₅, TiO₂, La₂O₅, CeO₂, ZrO₂, HfO₂, SrTiO₃, and Pr₂O₃. Further, it is possible to effectively use a material such as Zr silicate or Hf silicate which is composed of silicon oxide into which metal ions are mixed or a combination of these materials. It is preferable to appropriately select such a material as is required for each generation of transistors.

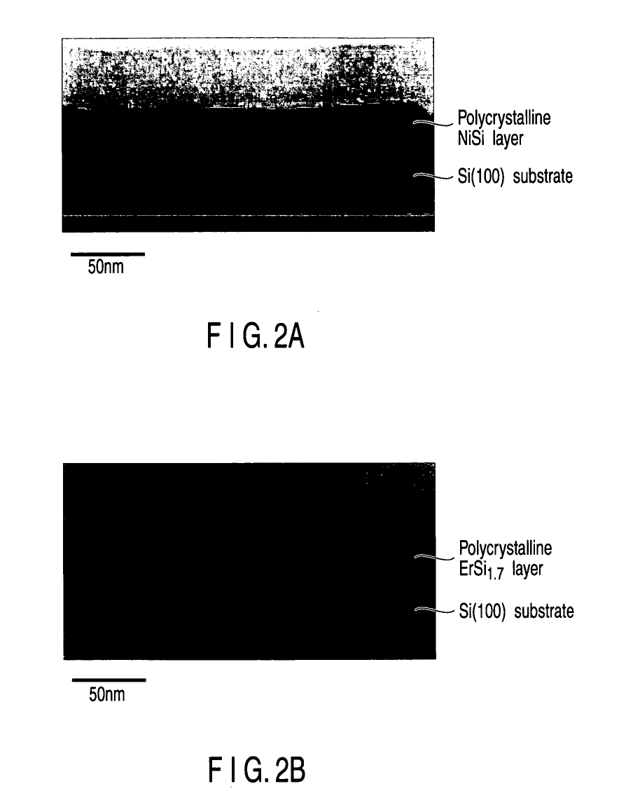

FIGS. 2A and 2B show the transmission electron microscopy (TEM) images of the interface of a silicide layer deposited on an Si(100) substrate. FIG. 2A shows a conventional NiSi layer. FIG. 2B is a TEM photograph of an ErSi_{1.7} layer. NiSi was formed by depositing Ni on an Si(100) substrate and thermally treating at 400° C. ErSi_{1.7} was formed by depositing Er film on the Si(100) substrate and then thermally treating at 700° C. A characteristic X ray analysis indicates that the composition of the obtained silicide is ErSi_{1.7}.

In spite of its polycrystalline structure, ErSi_{1.7} is distinctly oriented with respect to the Si substrate. ErSi_{1.7} layer has an interface between itself and Si substrate which interface is flat at the atomic level. ErSi_{1.7} has a hexagonal AlB₂ structure and has a very insignificant lattice mismatch with an Si(111) face. Accordingly, ErSi_{1.7} can grow epitaxially on the Si(111) substrate to form a flat interface at the atomic level. The Si(100) substrate has a somewhat significant lattice mismatch, so that ErSi_{1.7} does not grow epitaxially. However, ErSi_{1.7} becomes polycrystalline to suppress the lattice mismatch, thus forming a polycrystal having an interface that is flat at the atomic level.

Accordingly, ErSi_{1.7} makes it possible to form an ErSi_{1.7}/Si interface that is flat at the atomic level, either on the Si(100) substrate or on the Si(111) substrate. As shown in FIG. 2B, the ErSi_{1.7}/Si interface has a surface flatness (interface roughness) of at most 5 nm. In contrast, with NiSi is formed on the Si(100) substrate, the interface roughness is as much as 10 nm as shown in FIG. 2A.

FIG. 3 shows reverse-direction leakage currents in an NiSi/Si Schottky diode and an ErSi_{1.7}/Si Schottky diode. The leakage current in ErSi_{1.7} is markedly smaller than that in NiSi. This electrically indicates that the ErSi_{1.7} interface shown in FIG. 2B is flat. In a MOSFET, a diffusion region/Si substrate junction interface is formed immediately below silicide/Si (diffusion region). Accordingly, provided that the overlying silicide/Si (diffusion region) interface is flat, the diffusion region/Si substrate junction leakage current attributed to silicide is naturally small.

In this embodiment, the ErSi_{1.7} layer is inserted between NiSi and the diffusion region to form an NiSi/ErSi_{1.7} stacked silicide structure. This enables the formation of a silicide/Si interface that is flat at the atomic level. It is thus possible to inhibit a junction leakage current. Further, ErSi_{1.7} forms a Schottky barrier to electrons which has a height of about 0.24 eV, which is smaller than that of C54-TiSi₂, CoSi₂, NiSi, or Pd₂Si. This reduces a contact resistance that is a series resistance component of a channel resistance. As a result, a transistor is obtained which can operate at high speed with reduced power consumption.

In this embodiment, ErSi_{1.7} is used as silicide for insertion. However, silicide is not limited to ErSi_{1.7}. It is possible to use, as an interfacial layer, an arbitrary metal silicide which forms a Schottky barrier to electrons having a small height and which has a crystal structure similar to that of ErSi_{1.7} (hexagonal AlB₂ type), the metal silicide growing epitaxially on the Si(111) substrate. Specifically, the silicide may contain Gd, Tb, Dy, Ho, Er, Tm, Yb, or Lu, and similar effects are produced by using any of these materials.

FIGS. 4 to 6 show a method of manufacturing the semiconductor device shown in FIG. 1.

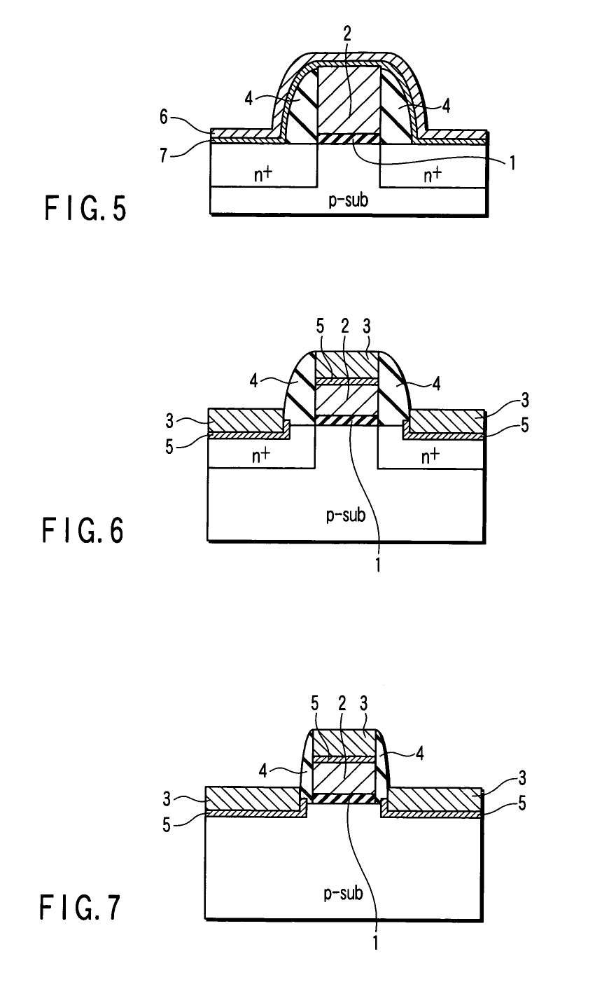

First, a surface of a p-type silicon substrate is thermally oxidized to form a gate insulating film 1 formed of a thermal-grown-silicon oxide film. A polycrystalline silicon layer is formed on the gate insulating film 1 by a CVD method, and then the polycrystalline silicon layer and gate insulating film selectively removed by lithography and reactive ion etching to form a gate electrode. Ion implantation of phosphorous ions is carried out to form a source/drain region of an n-type MOS transistor. Sidewalls 4 are formed to insulate the gate electrode from the source/drain region to obtain the structure shown in FIG. 4. Then, as shown in FIG. 5, an Er film 7 (film thickness 1 nm) and an Ni film 6 (film thickness 4 nm) are sequentially formed on the entire surface.

Moreover, thermal treatment is carried out at 450° C. to convert the Er film 7 and Ni film 6 on the polycrystalline silicon layer 2 and source/drain region into silicide. A mixed liquid of sulfuric acid and hydrogen peroxide is used to selectively remove unreacted Er and Ni on the gate sidewalls 4 to obtain the structure shown in FIG. 6.

In this case, the Er film 7 and the Ni film 6 are 1 nm and 4 nm, respectively, in film thickness. However, the film thickness is not limited to this. The film thickness of each metal film can be appropriately determined taking into account the film thickness of a silicide layer finally formed. Specifically, the film thickness of the Er film 7 is desirably selected so that the Er silicide (ErSi_{1.7}) layer 5, serving as an interfacial layer, has a film thickness of about 1 nm or more and about 5 nm or less. If a thickness of the ErSi_{1.7} layer 5 is too small, it is difficult to form a flat interface between the substrate and the ErSi_{1.7} layer. On the other hand, if a thickness of the ErSi_{1.7} layer 5 is too large, the transistor may be inhibited from operating successfully at high speed owing to the high resistivity of ErSi_{1.7}. The thickness of the ErSi_{1.7} layer 5 is desirably set to about 10 to 20 nm of the total thickness of the ErSi_{1.7} layer 5 and NiSi layer 3 formed thereon.

Ni silicide is mostly formed when Ni becomes as a diffusion species to diffuse through the Si substrate. In the above example, Er acts as a diffusion barrier to Ni to suppress the diffusion of Ni. For the reaction between Er and Si, Si mostly diffuses into Er. Accordingly, when the Ni/Er stack is converted into silicide, Si acts as a main diffusion species to form a stacked structure of ErSi_{1.7} and NiSi. It is also possible that Er interfacial layer can be formed with the combination of Er ion implantation and the Er-snowplow effect during Ni silicidation.

### Embodiment 2

FIG. 7 is a sectional view of a semiconductor device according to this embodiment.

In the illustrated semiconductor device, the gate sidewalls 4 have a small thickness of about 5 nm. This semiconductor device is similar to the structure in FIG. 1 except that a silicide stacked structure replaces the heavily impurity doped regions, that is, the source region and drain region. Such a structure is what is called a Schottky source/drain n-type MOS transistor.

This silicide layer has an interfacial layer at the interface between itself and the substrate, the interfacial layer comprising the ErSi_{1.7} layer 5. The interface between the ErSi_{1.7} layer 5 and the p-type Si substrate is flat at the atomic level. The NiSi layer 3 is formed on the interfacial layer. In a Schottky MOS transistor, a channel region and the silicide are in direct contact with each other without any heavily impurity doped region placed between the channel region and the silicide. Thus, the characteristics of the transistor are very sensitive to the shape of the silicide/Si interface compared to those of ordinary MOS transistors. This embodiment can control the interface between ErSi_{1.7} and Si so that the interface becomes flat at the atomic level. This makes it possible to inhibit the adverse effect of such a variation in the shape of the silicide/Si interface.

With a Schottky transistor, if silicide such as NiSi which has a low resistivity is used as a material for a source/drain electrode, a Schottky barrier remains at a source end even while the element device is in operation. This makes it impossible to provide a driving current equivalent to that obtained with an ordinary MOS transistor having a diffusion region. According to this embodiment, the interfacial layer between the silicide and Si is ErSi_{1.7}, which forms a Schottky barrier to electrons having a small height of 0.24 eV. This makes it possible to provide a driving current equivalent to that obtained with an ordinary MOS transistor having a diffusion region. Furthermore, in this stacked structure, a low-resistivity silicide is provided on the interfacial layer. This suppresses an increase in resistivity resulting from the use of a rare earth metal such as Er silicide. It is thus possible to reduce parasitic resistance to enable the transistor to operate at high speed with reduced power consumption.

### Embodiment 3

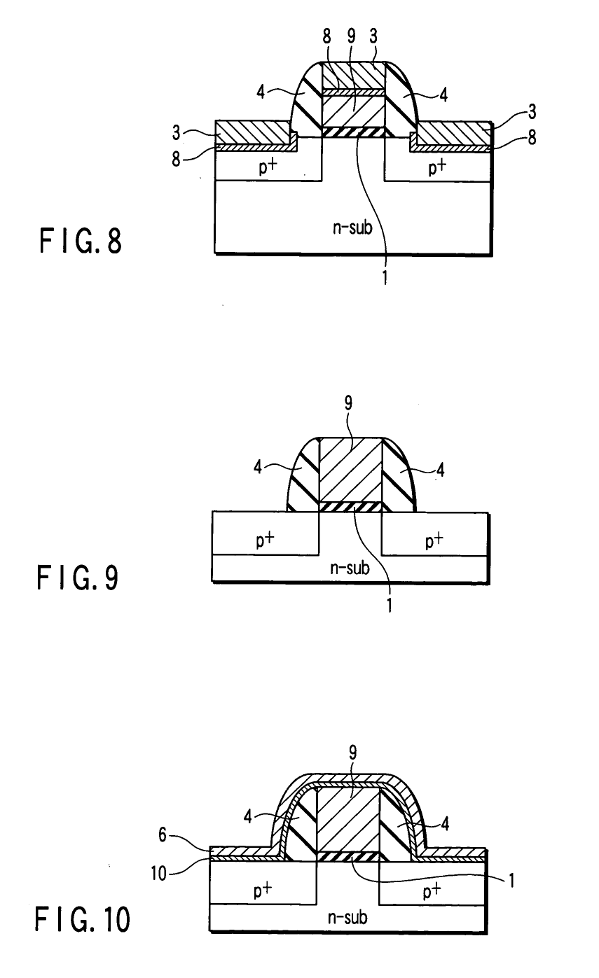

FIG. 8 is a sectional view of a semiconductor device according to this embodiment.

A gate electrode is formed on an n-type silicon substrate with the gate insulating film 1 formed of a thermal-grown-silicon oxide film interposed therebetween. The gate insulating film 1 desirably has a film thickness of at most 2 nm. The gate electrode has a structure in which heavily boron doped polycrystalline silicon 9, a PtSi layer 8, and the NiSi layer 3 are sequentially stacked. As shown in the figure, the gate sidewalls 4 formed of silicon oxide films are provided on sides of the gate insulating film and gate electrode to a film thickness of about 30 nm. A source region and a drain region are formed in the n-type silicon substrate so as to sandwich the gate insulating film between the source region and the drain region; the source region and the drain region are heavily p-type impurity doped regions.

A silicide layer is formed on these impurity regions. The silicide layer has an interfacial layer at the interface between itself and the heavily p-type impurity doped regions, the interfacial layer comprising the PtSi layer 8. The interface between the PtSi layer 8 and the heavily p-type impurity doped regions is flat at the atomic level. The NiSi layer 3 is provided on the interfacial layer. The PtSi layer 8 preferably has a film thickness of about 1 to 5 nm, and the NiSi layer 3 desirably has a film thickness of about 10 nm. Thus, a p-type MOS transistor is constructed on the n-type silicon substrate.

PtSi grows epitaxially on the Si(100) face and is more thermally stable than NiSi. Even when thermally treated at high temperature, PtSi is not subjected to aggregation or the like. This is because NiSi has a melting point of about 990° C., while PtSi has a higher melting point of about 1,230° C. As a result, in spite of its interface roughness of 2 to 5 nm, the PtSi/Si interface is flatter than the NiSi/Si interface. This inhibits the junction leakage current attributed to the irregularity of the silicide/Si interface.

PtSi offers a relatively high resistivity of about 35 μΩ·cm. However, the overlying low-resistivity NiSi layer suppresses an increase in resistance as in the case of ErSi_{1.7} according to the above embodiment 1. Further, PtSi forms a Schottky barrier to holes which has a height of about 0.2 eV, which is smaller than that of C54-TiSi₂, CoSi₂, or NiSi. This reduces the contact resistance and thus the power consumption. As a result, a p-type MOS transistor is obtained which can operate at high speed.

FIGS. 9 to 11 show a method for manufacturing the semiconductor device shown in FIG. 8.

First, a surface of an n-type silicon substrate is thermally oxidized to form a gate insulating film 1 formed of a thermal-grown-silicon oxide film. A polycrystalline silicon layer is formed on the gate insulating film 1 by the CVD method and then the polycrystalline silicon layer and gate insulating film selectively removed by lithography and reactive ion etching to form a gate electrode. Boron ions are implanted to form a source/drain region of a p-type MOS transistor. Sidewalls 4 are formed to insulate the gate electrode from the source/drain region to obtain the structure shown in FIG. 9. Then, as shown in FIG. 10, a Pt film 10 (film thickness 1 nm) and the Ni film 6 (film thickness 4 nm) are sequentially formed on the entire surface.

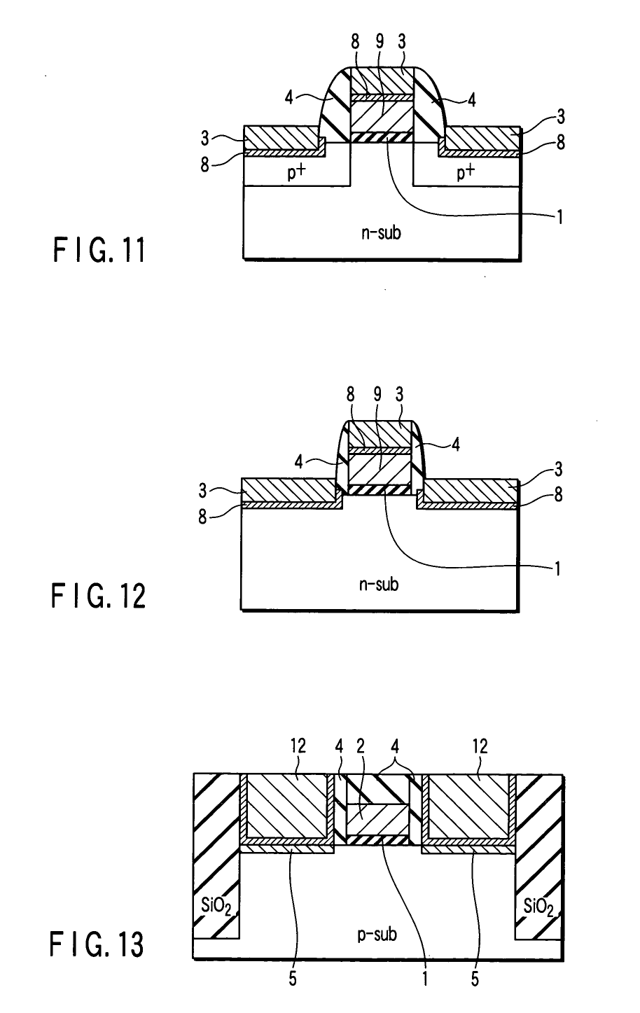

Moreover, thermal treatment is carried out at 450° C. to convert the Pt film 10 and Ni film 6 on the polycrystalline silicon layer 2 and source/drain region into silicide. Sulfuric acid and aqua regia are used to selectively remove unreacted Pt and Ni on the gate sidewalls 4 to obtain the structure shown in FIG. 11.

In this case, the Pt film 10 and the Ni film 6 are 1 nm and 4 nm, respectively, in film thickness. However, the film thickness is not limited to this. The film thickness of each metal film can be appropriately determined taking into account the film thickness of a silicide layer finally formed. Specifically, the film thickness of the Pt film 10 is desirably selected so that the PtSi layer 8, serving as an interfacial layer, has a film thickness of about 1 to 5 nm. If the thickness of the PtSi layer 8 is too small, it is difficult to form a flat interface between the substrate and the PtSi layer. If the thickness of the PtSi layer 8 is too large, the transistor may be inhibited from operating successfully at high speed owing to the high resistivity of PtSi. The thickness of the PtSi layer 8 is desirably set to about 10 to 20 nm of the total thickness of the PtSi layer 8 and NiSi layer 3 formed thereon.

### Embodiment 4

FIG. 12 is a sectional view of a semiconductor device according to this embodiment.

In the illustrated semiconductor device, the gate sidewalls 4 have a small thickness of about 5 nm. This semiconductor device is similar to the structure in FIG. 8 except that a silicide stacked structure replaces the heavily impurity doped regions, that is, the source region and drain region. Such a structure is what is called a Schottky source drain p-type MOS transistor.

This silicide layer has an interfacial layer at the interface between itself and the substrate, the interfacial layer comprising the PtSi layer 8. The interface between the PtSi layer and the n-type silicon substrate is flat at the atomic level. The NiSi layer 3 is formed on the interfacial layer. In this embodiment, as in the case of Embodiment 2, the use of PtSi, having a smaller interface roughness than NiSi, makes it possible to suppress a variation in the shape of the silicide/Si interface. Furthermore, PtSi forms a barrier to holes having a small of about 0.2 eV, and in this stacked structure, the low-resistivity silicide is provided on PtSi. As a result, as in the case of the n-type MOS transistor according to Embodiment 2, a driving current is obtained to reduce the parasitic resistance. Therefore, a transistor is obtained which can operate at high speed with reduced power consumption.

### Embodiment 5

FIG. 13 is a sectional view of a semiconductor device according to this embodiment.

A transistor is formed on a p-type silicon substrate. The structure of a gate electrode of the transistor is similar to that in Embodiment 3. The gate sidewalls 4 desirably have a small thickness of about 5 nm. A top surface of the gate electrode is covered with a silicon nitride film 4. Moreover, this structure corresponds to a Schottky source/drain n-type MOS transistor in which a silicide stacked structure replaces the heavily impurity doped regions, that is, the source region and drain region.

This silicide layer has an interfacial layer at the interface between itself and the substrate, the interfacial layer comprising the ErSi_{1.7} layer 5. The interface between the ErSi_{1.7} layer 5 and the p-type silicon substrate is flat at the atomic level. A Cu layer 12 is provided on the interfacial layer.

In this embodiment, as in the case of Embodiment 2, the use of ErSi_{1.7}, having an interface roughness that can be controlled at the atomic level, makes it possible to suppress a variation in the shape of the silicide/Si interface. As described above, ErSi_{1.7}, serving as an interfacial layer, forms a barrier to electrons having a small height of about 0.2 eV. In this stacked structure, Cu, offering a lower resistivity than silicide, is provided on the interfacial layer. This serves to provide a sufficient driving current. As a result, the parasitic resistance can be reduced to enable the transistor to operate at high speed with reduced power consumption.

This is not limited to the n-type MOS and similar effects can also be produced with a p-type MOS. In this case, by replacing ErSi_{1.7} with PtSi, it is possible to also reduce the contact resistance. Further, the layer on the interfacial layer may be composed of metal such as Al which offers a low resistivity of at most 20 μΩ·cm or its nitride. In any case, similar effects are produced.

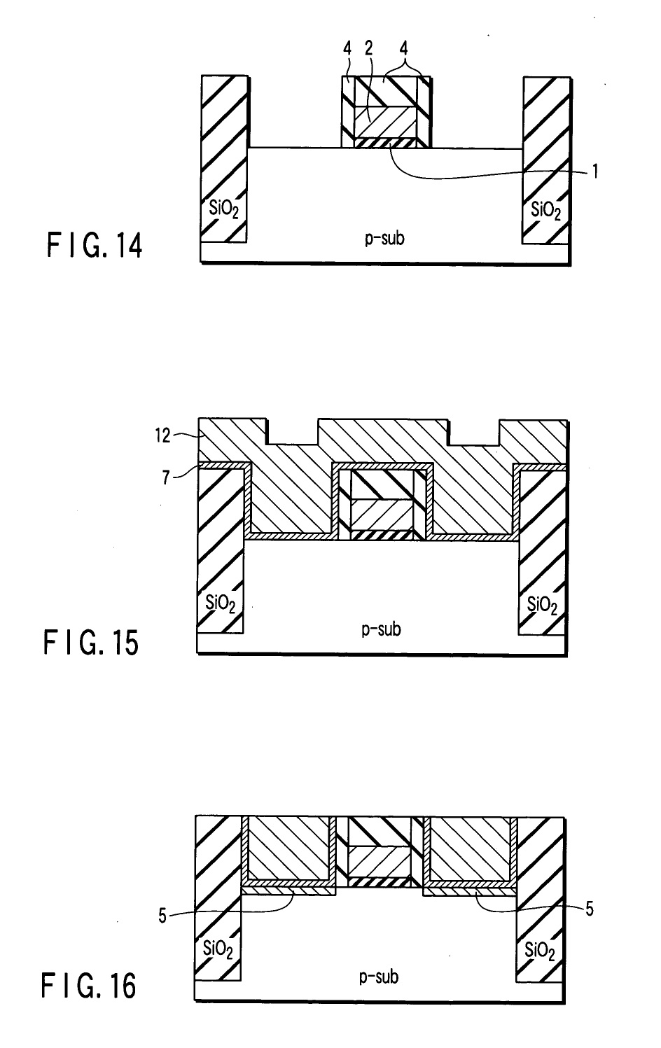

FIGS. 14 to 16 show a method for manufacturing the semiconductor shown in FIG. 13.

First, element device isolations are formed in a p-type silicon substrate by a shallow trench method. A surface of the substrate is thermally oxidized to form a gate insulating film 1 formed of a thermal-grown-silicon oxide film 1. Subsequently, a polycrystalline silicon layer is formed by CVD and then the polycrystalline silicon layer and gate insulating film selectively removed by lithography and reactive ion etching to form a gate electrode. Then, the sidewalls 4 are formed to insulate the gate electrode from the source/drain region.

An interlayer insulating film comprising SiO₂ is deposited on the entire surface. The interlayer insulating film is then removed only from the source/drain portion by lithography and reactive ion etching to obtain the structure shown in FIG. 14. Then, as shown in FIG. 15, the Er film 7 (1 nm) and the Cu film 12 (about 1 μm) are sequentially deposited on the entire surface to bury the contact region.

Moreover, thermal treatment is carried out at 450° C. to convert parts of the Er film 7 which are in contact with the Si substrate, into silicide. Subsequently, the overlying excess portion of Cu and Er is removed by CMP to obtain the structure shown in FIG. 16. This process enables the formation of not only silicide but also metal such that they are in self-alignment with the source/drain region.

### Embodiment 6

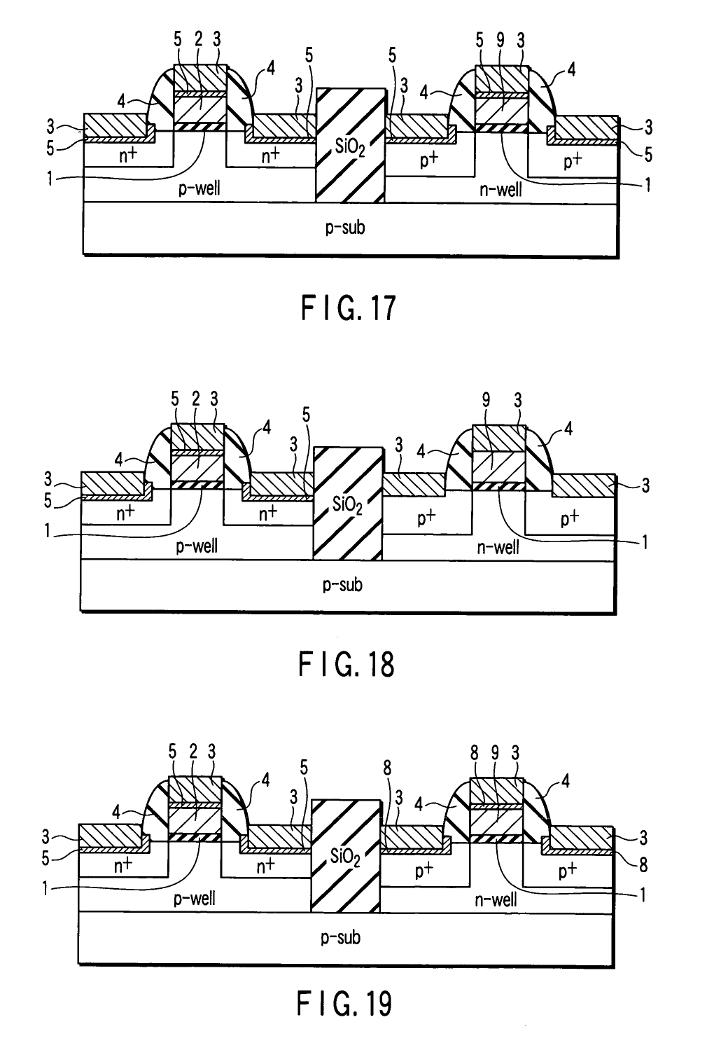

FIG. 17 is a sectional view of a semiconductor device according to this embodiment.

A p-type impurity region (p-type well) and an n-type impurity region (n-type well) are separately formed in a p-type silicon substrate. An n-type MOS transistor is provided in the p-type impurity region and has a configuration basically similar to that shown in FIG. 1. A p-type MOS transistor is provided in the n-type impurity region and has a contact structure similar to that of n-type MOS transistor. That is, ErSi_{1.7} is provided at the interface between the NiSi layer and the heavily p-type or n-type impurity doped source/drain region.

The n-type MOS transistor and the p-type MOS transistor operate complementarily to constitute a CMOS device. In this stacked structure, NiSi is formed on ErSi_{1.7}. Consequently, as in the case of Embodiment 1, the underlying ErSi_{1.7} layer enables the interface with the Si diffusion region to be formed flat at the atomic level. Moreover, the overlying NiSi layer reduces the resistivity of the contact layer.

### Embodiment 7

FIG. 18 is a sectional view of a semiconductor device according to this embodiment.

A p-type impurity region (p-type well) and an n-type impurity region (n-type well) are separately formed in a p-type silicon substrate. An n-type MOS transistor is provided in the p-type impurity region and has a configuration basically similar to that shown in FIG. 1. A p-type MOS transistor is provided in the n-type impurity region. In the p-type MOS transistor, the NiSi layer 3 is formed on the gate electrode and the source/drain diffusion region.

The n-type MOS transistor and the p-type MOS transistor operate complementarily to constitute a CMOS device. In this embodiment, an ErSi_{1.7}/NiSi stacked silicide structure is applied only to the n-type MOS transistor of the CMOS structure. Arsenic and phosphorous doped as impurities have a diffusion coefficient in Si which is one order of magnitude smaller than that of boron. Thus, the n-type MOS transistor has a smaller diffusion region depth immediately below the source/drain region than the p-type MOS transistor. In the n-type MOS transistor, leakage caused by the roughness of the silicide/Si interface is marked. This embodiment can effectively suppress the roughness of the silicide/Si interface of the n-type MOS transistor and reduce the contact resistance.

### Embodiment 8

FIG. 19 is a sectional view of a semiconductor device according to this embodiment.

A p-type impurity region (p-type well) and an n-type impurity region (n-type well) are separately formed in a p-type silicon substrate. An n-type MOS transistor is provided in the p-type impurity region and has a configuration basically similar to that shown in FIG. 1. A p-type MOS transistor is provided in the n-type impurity region and has a configuration basically similar to that shown in FIG. 8.

In this embodiment, the ErSi_{1.7}/NiSi stacked silicide structure is applied to the n-type MOS region to form a silicide/Si interface that is flat at the atomic level. PtSi, used in the source/drain region of the p-type MOS region, grows epitaxially on the Si(100) face. PtSi thus serves to form a flatter interface than NiSi. Further, the overlying NiSi layer reduces the resistivity.

If a single layer of low-resistivity silicide such as TiSi₂, CoSi₂, or NiSi is used as a contact material for a source/drain electrode, the resulting work function is close to a center of an Si forbidden band. Thus, a Schottky barrier height is about 0.5 to 0.6 eV for both electrons and holes. In this case, both conductive types can offer a similar contact resistance. However, if the silicon substrate has an impurity concentration of about 3×10²⁰ cm⁻³, the contact resistance is about 1×10⁻⁷ Ω·cm². This fails to meet the request value (6×10⁻⁸ Ω·cm²) for the contact resistance for the 45-nm technology generation specified in the international semiconductor road map.

According to this embodiment, the n-type MOS transistor contains ErSi_{1.7}, which is a material forming a low Schottky barrier (0.2 to 0.3 eV) to electrons. On the other hand, the p-type MOS transistor contains PtSi, which is a material forming a low Schottky barrier (0.2 to 0.3 eV) to holes. Thus, with the same impurity concentration of about 3×10²⁰ cm⁻³, the contact resistance decreases to at most 1×10⁻⁸ Ω·cm². The requirement for the contact resistance for a 22-nm technology generation is met. Further, the formation of a flat interface can be accomplished simultaneously with the reduction in contact resistance.

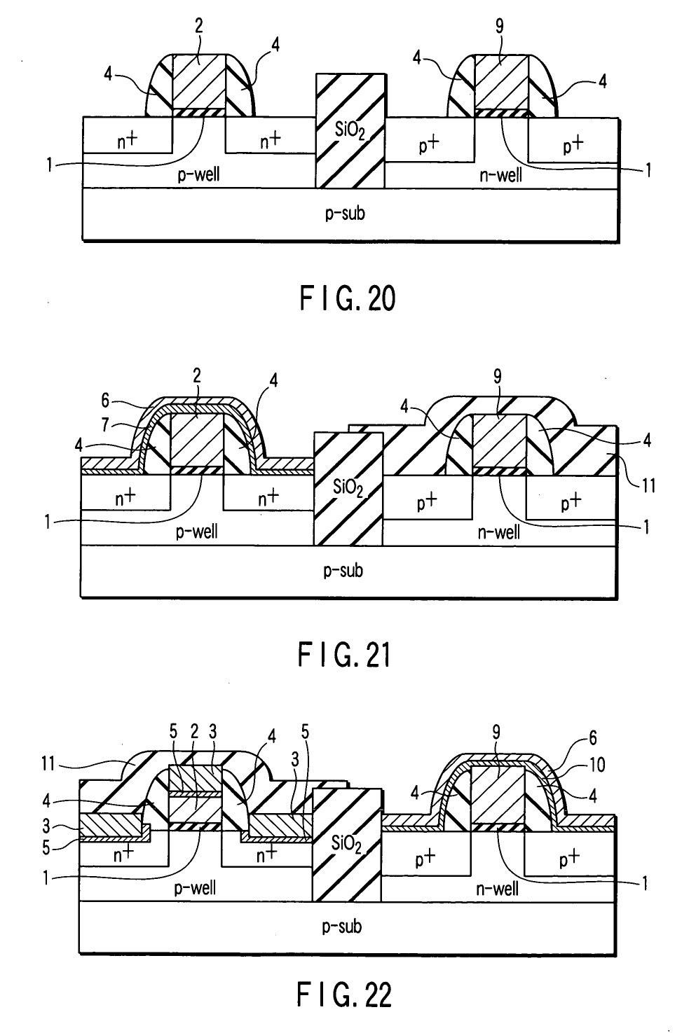

FIGS. 20 to 23 show a method for manufacturing the semiconductor device shown in FIG. 19.

First, a p-type impurity region (p-type well) and an n-type impurity region (n-type well) are formed in a p-type silicon substrate by ion implantation. Then, an element device isolation is formed in the p-type silicon substrate by the shallow trench method. A surface of the substrate is thermally oxidized to form a gate insulating film 1 formed of a thermal-grown-silicon oxide film 1. Subsequently, a polycrystalline silicon layer is formed by CVD. Then, the polycrystalline silicon layer and gate insulating film selectively removed by lithography and reactive ion etching to form a gate electrode. Ion implantation of arsenic and boron ions is carried out to form a heavily impurity doped region in the source/drain regions and gate electrodes of the n- and p-type MOS transistors. Then, the sidewalls 4 are formed to insulate the gate electrode from the source/drain region to obtain the structure shown in FIG. 20.

The p-type MOS region is masked with an oxide film 11 by the CVD process and the lithography process. Then, as shown in FIG. 21, the Er film 7 (film thickness 1 nm) and the Ni film 6 (film thickness 4 nm) are formed on the n-type region by sputtering.

Then, thermal treatment is carried out at 450° C. to convert the Er film 7 and Ni film 6 into silicide. A mixed liquid of sulfuric acid and hydrogen peroxide is then used to selectively remove unreacted Er and Ni to form an ErSi_{1.7}/NiSi structure in the gate electrode and source/drain region of the n-type MOS region. Subsequently, the oxide film 11 is removed from the p-type MOS region by etching, while the n-type MOS region is masked with the oxide film 11. Moreover, as shown in FIG. 22, the Pt film 10 (film thickness 1 nm) and the Ni film 6 (4 nm) are selectively formed on the p-type MOS region.

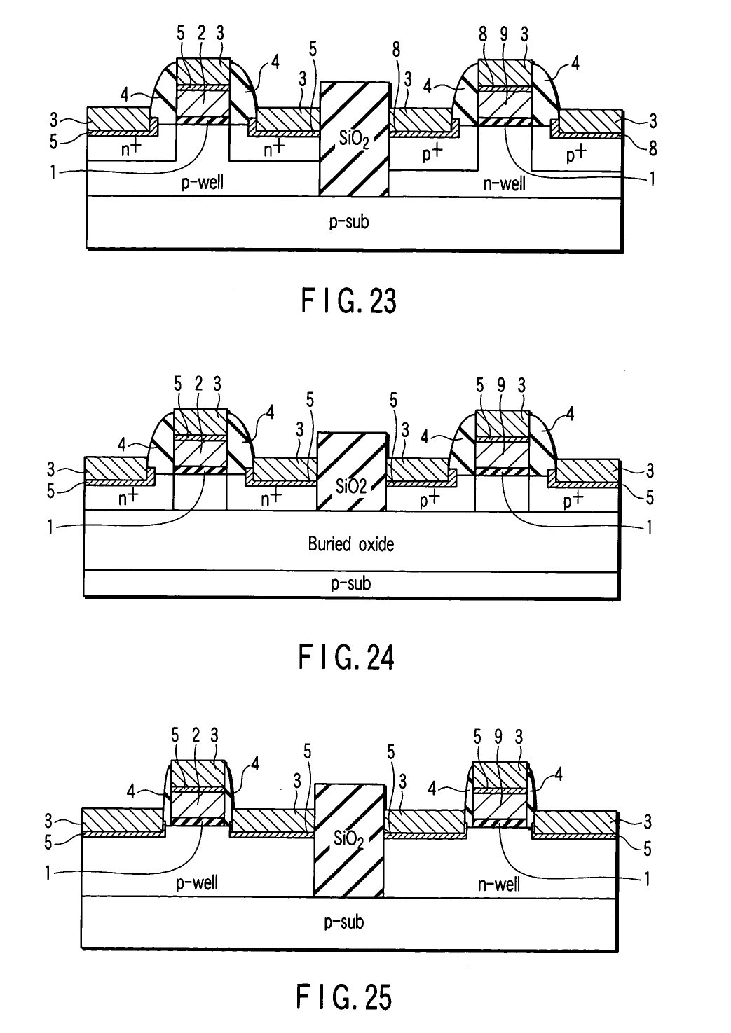

Subsequently, thermal treatment is carried out at 450° C. to convert the Pt film 10 and Ni film 6 into silicide. Aqua regia and a mixed liquid of sulfuric acid and hydrogen peroxide are then used to selectively remove unreacted Pt and Ni to form an PtSi/NiSi stacked structure in the gate electrode and source/drain region of the p-type MOS region. Finally, the cap oxide film 11 is removed from the n-type MOS region to obtain the structure shown in FIG. 23.

Er is readily oxidized in the air. Accordingly, when Er is converted into silicide, the interface of silicide may be roughened by oxygen unless it is protected by a cap layer of an anti-oxidant film. With the forming process according to this embodiment, immediately after an Er film has been formed, an Ni film is formed on the Er film. This makes it possible to avoid the contamination of Er with oxygen or the like.

In the embodiments below, the ErSi_{1.7}/NiSi stacked structure is used in both n-type MOS region and p-type MOS region. However, as in the case of Embodiments 7 and 8, the ErSi_{1.7}/NiSi stacked structure may be applied only to the n-type MOS region, with the NiSi or PtSi/NiSi structure applied to the p-type MOS region.

### Embodiment 9

FIG. 24 is a sectional view of a semiconductor device according to this embodiment.

A silicon oxide film is formed on a p-type silicon substrate. A single crystalline silicon layer serving as an active region of a MOS transistor is formed on the silicon oxide film to form an SOI structure. The single crystalline silicon layer serving as an active region is desirably about 5 to 10 nm in thickness. N- and p-type MOS transistors are formed on the SOI substrate to constitute a CMOS device. The structure of the transistors formed is basically the same as that shown in FIG. 17 and described in Embodiment 6.

A silicide layer is formed on the source/drain region so as to form a stacked structure. Both n- and p-type MOS regions have the ErSi_{1.7} layer 5 as an interfacial layer between themselves and the substrate. The NiSi layer 3 is formed on the ErSi_{1.7} layer 5. In this embodiment, all of the channel portion is depleted, so that what is called a complete depletion type SOI-MOS transistor is provided. In the complete depletion type SOI device, the single crystalline silicon layer serving as an active region is very thin. In this case, when the silicide/Si interface of the source/drain portion is very irregular, the silicide layer partly reaches the buried oxide film. This may cause a variation in characteristics among element devices. Further, if the depth of silicide fully reaches the buried oxide film layer, the silicide/Si contact area is equal to the SOI film thickness multiplied by the gate width and is extremely small. This increases the contact resistance to degrade the performance of the transistor.

It is therefore essential to control the silicide/Si interface at the atomic level. Further, if the thickness of Si required to form silicide is larger than that of the single crystalline silicon layer serving as an active region, an S/D elevate structure may be appropriately used. Moreover, even for a double-gate complete-depletion type device having a three-dimensional structure represented by a Fin type transistor, its channel must have a thickness at most half to one-third of the gate length in order to suppress a channel effect. The structure of this embodiment is also applicable in this case. This embodiment produces significant effects it can control the interface at the atomic level.

### Embodiment 10

FIG. 25 is a sectional view of a semiconductor device according to this embodiment.

A p-type impurity region (p-type well) and an n-type impurity region (n-type well) are separately formed in a p-type silicon substrate. The structures of gate electrodes of transistors formed on these impurity regions are basically similar to those shown in FIG. 24 and described in Embodiment 9.

Both p-type MOS transistor and n-type MOS transistor are Schottky source/drain MOS transistors in which a silicide stacked structure replaces the heavily impurity doped regions, that is, the source region and drain region. Both n- and p-type MOS regions have the ErSi_{1.7} layer 5 as an interfacial layer between themselves and the substrate. The NiSi layer 3 is formed on the ErSi_{1.7} layer 5.

In this embodiment, as in the case of Embodiment 2, the use of ErSi_{1.7} makes it possible to suppress a variation in the shape of the silicide/Si interface. Moreover, the overlying NiSi layer can inhibit an increase in resistivity to reduce the parasitic resistance. As a result, a transistor with a reduced power consumption is obtained.

Further, as in the case of Embodiment 7, for the p-type MOS, the PtSi layer 8 can be used as an interfacial layer in place of the ErSi_{1.7} layer 5. This reduces the magnitude of the Schottky barrier at the source end to drastically increase the driving current. It can also be combined with the SOI structure according to Embodiment 9.

### Embodiment 11

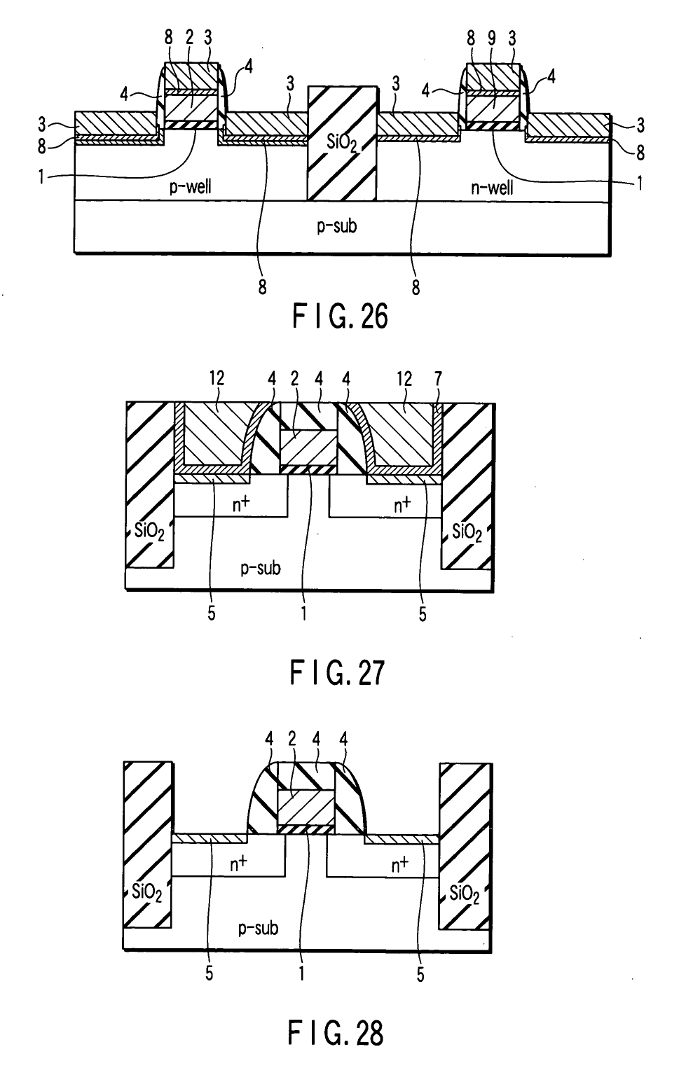

FIG. 26 is a sectional view of a semiconductor device according to this embodiment.

According to this embodiment, a p-type impurity region (p-type well) and an n-type impurity region (n-type well) are separately formed in a p-type silicon substrate. Gate electrodes of transistors formed on these impurity regions have the following structure: in the n-type MOS transistor, a PtSi/NiSi stacked silicide is stacked on heavily phosphorous doped polycrystalline silicon, and in the p-type MOS transistor, a PtSi/NiSi stacked silicide is stacked on heavily boron doped polycrystalline silicon.

For the source/drain region, the p-type MOS region has a Schottky junction PtSi/NiSi stacked structure similarly to the p-type PMOS according to Embodiment 4. The n-type MOS region has a several-nm steep heavily n-type impurity doped region at the PtSi/Si interface and is formed with the same PtSi/NiSi stacked silicide as that in the p-type MOS region. The heavily n-type impurity doped region has an appropriate thickness for complete depletion. The presence of such a heavily n-type impurity doped region effectively reduces the height of a Schottky barrier may be formed at the PtSi/Si interface. Thus, even with PtSi having a high Schottky barrier to electrons, a sufficient driving current for the transistor can be obtained.

To form a steep heavily impurity doped region, it is preferable to use the segregation effect of impurities; under this effect, the impurities are segregated from the layer and move to the interface during the formation of PtSi. If Pt and Si react with each other to form Pt silicide, the impurities in Si such as arsenic or phosphorous are segregated from Si and move to the interface without being dissolved into PtSi. This “snowplow phenomenon” serves to form a several-nm steep heavily n-type impurity doped region. The use of a stacked PtSi/NiSi structure produces effects similar to those of Embodiment 2. Alternatively, ErSi_{1.7} may be used in place of PtSi. Then, for the p-type MOS, acceptor type impurities such as In or B may be used to form a several-nm steep heavily p-type impurity doped region. For the n-type MOS transistor, a structure similar to that in Embodiment 1 may be used. Further, this structure may be combined with the above SOI structure.

### Embodiment 12

FIG. 27 is a sectional view of a semiconductor device according to this embodiment.

A transistor is formed on a p-type silicon substrate. The structure of a gate electrode of the transistor is similar to that in Embodiment 1. The gate sidewalls 4, formed of a silicon oxide film, are formed on the sides of the gate insulating film and gate electrode to a thickness of about 30 nm. A top surface of the gate electrode is covered with a silicon nitride film 4. Moreover, a source region and a drain region are formed on the p-type silicon substrate sandwiching the gate insulating film 1; the source and drain regions are heavily n-type impurity doped regions.

The silicide layer has an interfacial layer at the interface between itself and heavily n-type impurity doped regions, the interfacial layer comprising the ErSi_{1.7} layer 5. The interface between the ErSi_{1.7} layer 5 and the p-type silicon substrate is flat at the atomic level. The Cu layer 12 is provided on the interfacial layer.

In this embodiment, as in the case of Embodiment 1, the use of ErSi_{1.7}, having an interface roughness that can be controlled at the atomic level, makes it possible to suppress a variation in the shape of the silicide/Si interface. As described above, ErSi_{1.7}, serving as an interfacial layer, forms a barrier to electrons having a small height of about 0.2 eV. In this stacked structure, Cu, offering a lower resistivity than silicide, is provided on the interfacial layer. This serves to provide a sufficient driving current. As a result, the parasitic resistance can be reduced to enable the transistor to operate at high speed with a reduced power consumption.

This is not limited to the n-type MOS transistor and similar effects can also be produced with a p-type MOS transistor. In this case, by replacing ErSi_{1.7} with PtSi, it is also possible to reduce the contact resistance. Further, the layer on the interfacial layer may be composed of metal such as Al which offers a low resistivity of at most 20 μΩ·cm or its nitride. In any case, similar effects are produced.

FIGS. 28 to 30 show a method for manufacturing the semiconductor shown in FIG. 27.

First, element device isolations are formed in a p-type silicon substrate by the shallow trench method. A surface of the substrate is thermally oxidized to form a gate insulating film 1 formed of a thermal-grown-silicon oxide film 1. Subsequently, a polycrystalline silicon layer is formed by CVD and then selectively removed by lithography to form a gate electrode. Then, phosphorous ions are implanted to form a source/drain region of an n-type MOS transistor. The sidewalls 4 are then formed to insulate the gate electrode from the source/drain region.

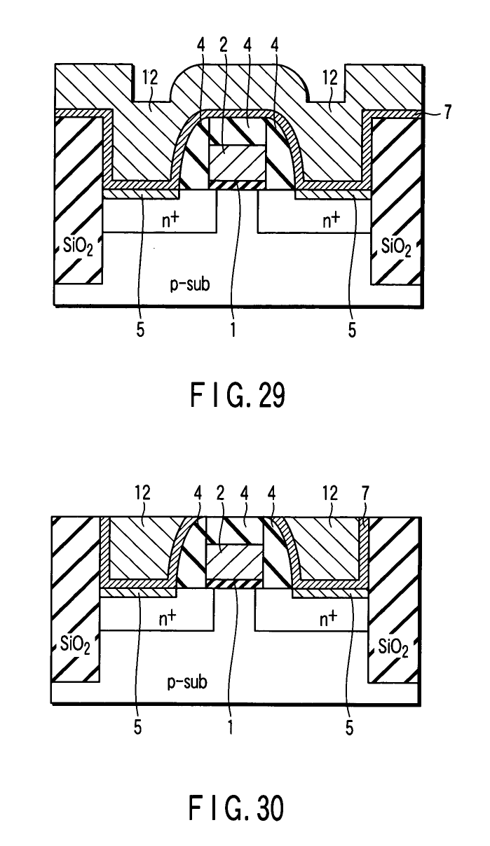

An interlayer insulating film comprising SiO₂ is deposited on the entire surface. The interlayer insulating film is then removed only from the source/drain portion by lithography and reactive ion etching to obtain the structure shown in FIG. 28. Then, as shown in FIG. 29, the Er film 7 (1 nm) and the Cu film 12 (about 1 μm) are sequentially deposited on the entire surface to bury the contact region.

Moreover, thermal treatment is carried out at 450° C. to convert parts of the Er film 7 which are in contact with the Si substrate, into silicide. Subsequently, CMP is used to remove the overlying excess portion of Cu and Er to obtain the structure shown in FIG. 30. This process enables the formation of not only silicide but also metal such that they are in self-alignment with the source/drain region.

In the description of the above example, Si is used for the channel region. However, it is possible to use SiGe, Ge, strained Si, or the like which has a higher mobility than Si. Alternatively, many variations may be made to the present invention without departing from the spirit of the present invention.

The embodiment of the present invention provides a semiconductor device comprising a silicide layer deposited on a substrate having an interface that is flat at the atomic level, the silicide layer offering only a low resistivity.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate having isolation regions; and
a MIS transistor comprising a gate electrode formed above the semiconductor substrate with a gate insulating film interposed therebetween, and a pair of contact layers formed on the semiconductor substrate sandwiching the gate electrode, the contact layers having an interfacial layer at an interface between the semiconductor substrate and the contact layers, the interfacial layer comprising a metal silicide containing at least one selected from a group consisting of Er, Gd, Tb, Dy, Ho, Tm, Yb, Lu, and Pt.

2. The semiconductor device according to claim 1, wherein the MIS transistor is of an n type, and the interfacial layer comprises Er silicide.

3. The semiconductor device according to claim 2, wherein the interfacial layer has a film thickness of at least 1 nm and at most 5 nm.

4. The semiconductor device according to claim 2, wherein the semiconductor device is formed of a complementary MIS transistor further comprising a p-type MIS transistor formed on the semiconductor substrate.

5. The semiconductor device according to claim 1, wherein the MIS transistor is of a p type, and the interfacial layer comprises Pt silicide.

6. The semiconductor device according to claim 5, wherein the interfacial layer has a film thickness of at least 2 nm and at most 3 nm.

7. The semiconductor device according to claim 5, wherein the semiconductor device is formed of a complementary MIS transistor further comprising a n-type MIS transistor formed on the semiconductor substrate.

8. The semiconductor device according to claim 1, wherein the contact layer further comprises a metal layer formed on the interfacial layer.

9. A semiconductor device comprising:
a semiconductor substrate having isolation regions; and
a MIS transistor comprising a gate electrode formed above the semiconductor substrate with a gate insulating film interposed therebetween, a pair of source/drain heavily impurity doped regions formed in the semiconductor substrate, and a pair of contact layers formed on the source/drain heavily impurity doped regions and having an interfacial layer at an interface, the interfacial layer comprising a metal silicide containing at least one selected from a group consisting of Er, Gd, Tb, Dy, Ho, Tm, Yb, Lu, and Pt.

10. The semiconductor device according to claim 9, wherein the MIS transistor is of an n type, and the interfacial layer comprises Er silicide.

11. The semiconductor device according to claim 10, wherein the interfacial layer has a film thickness of at least 1 nm and at most 5 nm.

12. The semiconductor device according to claim 10, wherein the semiconductor device is formed of a complementary MIS transistor further comprising a p-type MIS transistor formed on the semiconductor substrate.

13. The semiconductor device according to claim 9, wherein the MIS transistor is of a p type, and the interfacial layer comprises Pt silicide.

14. The semiconductor device according to claim 5, wherein the interfacial layer has a film thickness of at least 2 nm and at most 3 nm.

15. The semiconductor device according to claim 5, wherein the semiconductor device is formed of a complementary MIS transistor further comprising a n-type MIS transistor formed on the semiconductor substrate.

16. The semiconductor device according to claim 9, wherein the contact layer further comprises a metal layer formed on the interfacial layer.

17. A semiconductor device comprising:
a semiconductor substrate having isolation regions;
an n-type MIS transistor having a diffusion region formed in the semiconductor substrate, a gate electrode formed above the semiconductor substrate with a gate insulating film interposed therebetween, and a silicide layer formed above the diffusion region with a first interfacial layer interposed therebetween, the first interfacial layer comprising a metal silicide containing at least one selected from a group consisting of Er, Gd, Tb, Dy, Ho, Tm, Yb, Lu, and Pt; and
a p-type MIS transistor having a diffusion region formed in the semiconductor substrate, a gate electrode formed above the semiconductor substrate with a gate insulating film interposed therebetween, and a silicide layer formed above the diffusion region with a second interfacial layer interposed therebetween, the second interfacial layer comprising the metal silicide containing the same metal as the first interfacial layer in the n-type MIS transistor.

18. The semiconductor device according to claim 17, wherein the first interfacial layer comprises Er silicide.

19. The semiconductor device according to claim 17, wherein the semiconductor is formed of an SOI substrate.

20. The semiconductor device according to claim 17, wherein one of the n-type MIS transistor and the p-type MIS transistor comprises heavily doped impurity regions which is in contact with the interfacial layer.
